(19) United States
(12) Patent Application Publication
(10) Pub. No.: US 2014/0374006 A1
(43) Pub. Date: Dec. 25, 2014

(54) LIGHT RADIATION DEVICE AND METHOD FOR FABRICATING DISPLAY DEVICE USING THE SAME

(71) Applicant: Samsung Display Co., Ltd., Yongin-City (KR)

(72) Inventor: Yun Heum PARK, Busan (KR)

(73) Assignee: Samsung Display Co., Ltd., Yongin-City (KR)

(21) Appl. No.: 14/038,219

(22) Filed: Sep. 26, 2013

(30) Foreign Application Priority Data
Jun. 20, 2013 (KR) 10-2013-0070974

(51) Int. Cl. B32B 38/00

(52) U.S. Cl. CPC B32B 38/0008; B32B 2310/0837
USPC 156/108

(57) ABSTRACT

A light radiation device and method for fabricating the display device using the same. The light radiation device includes a light source generating light and a light guide unit guiding the light, wherein the light guide unit includes a cover portion covering the light source, and a guide portion projecting from the cover portion and including flexible optical fiber.

### CROSS-REFERENCE TO RELATED APPLICATION

This application claims priority from and the benefit of Korean Patent Application No. 10-2013-0070974, filed on Jun. 20, 2013 which is hereby incorporated by reference for all purposes as if fully set forth herein.

### BACKGROUND

1. Field

Exemplary embodiments of the present invention relate to a light radiation device and a method for fabricating a display device using the same.

2. Discussion of the Background

Recently, display devices have included thin-type flat panel displays, such as liquid crystal displays (LCD) and organic light emitting diodes (OLED).

In such a flat panel display, a window for protection is generally installed on a display panel on which an image is displayed. That is, in order to improve visibility of an image that is displayed on the display panel and impact resistance of the display device, the display panel and the window may be bonded together with a photo-curable adhesive. Specifically, after the display panel and the window are held in close contact with each other by the photo-curable adhesive, light is radiated thereon from an upper side of the window to cure the photo-curable adhesive and, thus the display panel and the window are firmly bonded to each other.

A black matrix may be formed on the window to cover the border of an image region of the display panel, and light is then prevented from easily passing through the black matrix. Accordingly, the photo-curable adhesive placed on a lower portion of the black matrix may not be sufficiently cured, thereby reducing the bonding quality between the display panel and the window.

In order to solve this problem, light may be radiated from not only an upper side of the window, but also a side portion of the window and, thus, a region where the light is intercepted by the black matrix may be eliminated.

However, in a region where a flexible printed circuit board is installed on the display panel, even the light that is radiated from the side, may be blocked by the flexible printed circuit board. For example, the flexible printed circuit board can electrically connect the display panel and a controller and can be bent very smoothly, and as a part of a body thereof is bent, it may hide the side portion of the photo-curable adhesive. In this case, curing of the photo-curable adhesive may not be sufficiently performed, and thus the display panel and the window may not be appropriately bonded to each other, thereby resulting in a reduction in product quality.

The above information disclosed in this Background section is only for enhancement of understanding of the background of the invention and therefore it may contain information that does not form the prior art that is already known in this country to a person of ordinary skill in the art.

### SUMMARY

Exemplary embodiments of the present invention provide a light radiation device which can be used to cure a photo-curable adhesive and in which a light guide unit that includes flexible optical fiber is installed.

Exemplary embodiments of the present invention also provide a method for fabricating a display device, which can firmly bond a display panel and a window to each other through secure curing of a photo-curable adhesive using a light radiation device in which a light guide unit that includes flexible optical fiber is installed.

Additional features of the invention will be set forth in the description which follows, and in part will become apparent from the description, or may be learned from practice of the invention.

An exemplary embodiment of the present invention discloses a light radiation device including a light source generating light, and a light guide unit guiding the light, wherein the light guide unit includes a cover portion covering the light source, and a guide portion projecting from the cover portion and including a flexible optical fiber.

An exemplary embodiment of the present invention also discloses a method for fabricating a display device, including bonding a display panel and a window to each other using a photo-curable adhesive, and curing the photo-curable adhesive using a light radiation device, wherein the light radiation device includes a light source generating light, and a light guide unit guiding the light, wherein the light guide unit includes a cover portion covering the light source, and a guide portion projecting from the cover portion and including a flexible optical fiber.

An exemplary embodiment of the present invention also discloses a method for fabricating a display device, including bonding a display panel and a window to each other using a photo-curable adhesive, and curing the photo-curable adhesive by making a light radiation device come in direct contact with at least one of the display panel, the window, and the photo-curable adhesive.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiments of the invention, and together with the description serve to explain the principles of the invention.

FIG. 1 is a cross-sectional view of a light radiation device according to an exemplary embodiment of the present invention.

FIG. 2 is an enlarged cross-sectional view of a part of the light radiation device of FIG. 1.

FIG. 3 is a cross-sectional view illustrating an arrangement of a display panel and a window according to an exemplary embodiment of the present invention.

FIG. 4 is a cross-sectional view illustrating movement of a light radiation device in a direction where a display panel and a window are located according to an exemplary embodiment of the present invention.

FIG. 5 is a cross-sectional view illustrating filling of a space between a display panel and a window according to an exemplary embodiment of the present invention.

FIG. 6 is a cross-sectional view of a light radiation device according to another exemplary embodiment of the present invention.

FIG. 7 is an enlarged cross-sectional view of a part of the light radiation device of FIG. 6.

FIG. 8 is a cross-sectional view illustrating insertion of a guide portion of a light radiation device between a display panel and a window according to another exemplary embodiment of the present invention.

FIG. 9 is a cross-sectional view illustrating an arrangement of a display panel and a window according to still another exemplary embodiment of the present invention.

FIG. 10 is a cross-sectional view illustrating passing of a display panel and a window between light radiation devices according to still another exemplary embodiment of the present invention.

### DETAILED DESCRIPTION OF THE ILLUSTRATED EMBODIMENTS

The invention is described more fully hereinafter with reference to the accompanying drawings, in which exemplary embodiments of the invention are shown. This invention may, however, be embodied in many different forms and should not be construed as limited to the exemplary embodiments set forth herein. Rather, these exemplary embodiments are provided so that this disclosure is thorough, and will fully convey the scope of the invention to those skilled in the art. In the drawings, the size and relative sizes of elements may be exaggerated for clarity. Like reference numerals in the drawings denote like elements.

It will be understood that when an element or layer is referred to as being “on” or “connected to” another element or layer, it can be directly on or directly connected to the other element or layer, or intervening elements or layers may be present. In contrast, when an element or layer is referred to as being “directly on” or “directly connected to” another element or layer, there are no intervening elements or layers present. It will be understood that for the purposes of this disclosure, “at least one of X, Y, and Z” can be construed as X only, Y only, Z only, or any combination of two or more items X, Y, and Z (e.g., XYZ, XYY, YZ, ZZ).

Although the terms “first, second, and so forth” are used to describe diverse constituent elements, such constituent elements are not limited by the terms. The terms are used only to discriminate a constituent element from other constituent elements. Accordingly, in the following description, a first constituent element may be a second constituent element.

Hereinafter, exemplary embodiments of the present invention will be described with reference to the drawings.

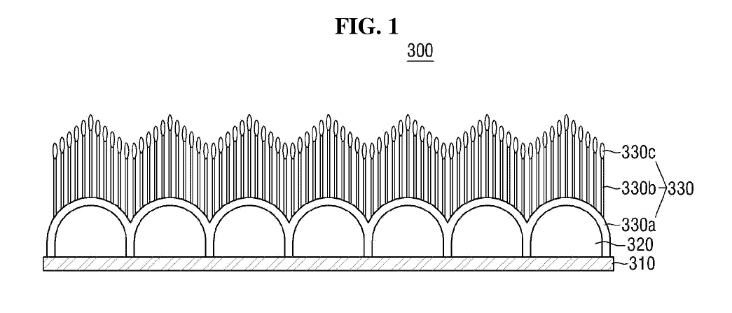

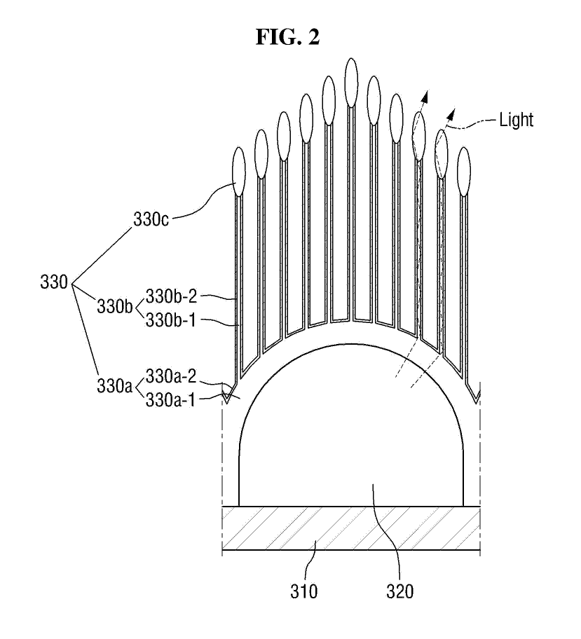

FIG. 1 is a cross-sectional view of a light radiation device 300 according to an exemplary embodiment of the present invention, and FIG. 2 is an enlarged cross-sectional view of a part of the light radiation device 300 of FIG. 1.

Referring to FIGS. 1 and 2, the light radiation device 300 may include a base substrate 310, a light source 320, and a light guide unit 330.

The light radiation device 300 may be used in various fields. For example, the light radiation device 300 may be used as a simple illumination device. Further, the light radiation device 300 may be used for the purpose of curing a photo-curable material. In an exemplary embodiment, the light radiation device 300 may be used to cure a photo-curable adhesive 150 for bonding a display panel 110 and a window 120 to each other, but is not limited thereto.

The base substrate 310 may support the light source 320 and the light guide unit 330. In an exemplary embodiment, the base substrate 310 may be in the shape of a plate, but is not limited thereto. The base substrate 310 may have various shapes depending on the number of light sources 320 and the arrangement thereof. Further, although not illustrated in FIG. 1, the base substrate 310 may include connection wirings connected to the light sources 320 and a power supply portion applying a voltage to the connection wirings.

The base substrate 310 may be made of an organic material, an inorganic material, or a combination of the organic material and the inorganic material. In an exemplary embodiment, the base substrate 310 may include a reflective material. Here, the reflective material may be applied onto a surface on which the light source 320 is arranged. The reflective material may reflect the light generated from the light source 320. As described above, the base substrate 310, like the light guide unit 330, may also operate to guide the light. In another exemplary embodiment, the base substrate 310 may include the same materials as a second cover portion 330a-2 and a second guide portion 330b-2, to be described later.

The light source 320 may be located on the base substrate 310. The light source 320 may generate light. The light source 320 may be, for example, an LED (Light Emitting Diode), a CCFL (Cold Cathode Fluorescent Lamp), a HCFL (Hot Cathode Fluorescent Lamp), or an EEFL (External Electrode Fluorescent Lamp). Further, the light generated from the light source 320 may be infrared light, visible light, or ultraviolet light. In an exemplary embodiment, the light source 320 may be an LED that generates ultraviolet light, but is not limited thereto. Various light sources 320 and light combinations are possible.

At least two light sources 320 may be provided. In an exemplary embodiment, light sources 320 may be arranged in the form of a matrix on the base substrate 310. In a cross-sectional view, the light sources 320 may be arranged in a line, with adjacent light sources 320 spaced apart from each other. However, the arrangement of the light sources 320 is not limited thereto, and the light sources 320 may be arranged to come in contact with each other.

One surface of the light source 320 may be a planar surface, and the other surface thereof may be a curved surface. In an exemplary embodiment, the planar surface may come in contact with the base substrate 310, and the curved surface may come in contact with the light guide unit 330.

The light guide unit 330 may guide the light generated from the light source 320. Here, “guide the light” refers to directing the light in a desired direction.

The light guide unit 330 may be separated from the light source 320. In other words, the light source 320 and the light guide unit 330 may be detachable. By configuring the light source 320 and the light guide unit 330 to be detachable, the light guide unit 330 is attached to the light source 320 in the field where the light guide is necessary, while the light guide unit 330 is separated from the light source 320 in the field where the light guide is not necessary. In an exemplary embodiment, by attaching the light guide unit 330 to the existing light source 320, the light radiation device 300 according to an exemplary embodiment of the present invention may be configured. As described above, if the light radiation device 300 is configured through attachment of the light guide unit 330 to the light source 320, the light source 320 can be used as it is, and equipment utilization is increased. Further, since only the light guide unit 330 is additionally fabricated, a cost saving can be achieved.

The light guide unit 330 may include a cover portion 330a, a guide portion 330b, and an emission portion 330c.

The cover portion 330a may cover the light source 320. In an exemplary embodiment, the cover portion 330a may surround one surface of the light source 30 that does not come in contact with the base substrate 310. In other words, the cover portion 330a may cover the one surface of the light source 320 that is a curved surface. The cover portion 330a and the base substrate 310 may completely surround the light source 320.

The cover portion 330a may include a first cover portion 330a-1 and a second cover portion 330a-2.

The first cover portion 330a-1 may come in direction contact with the light source 320. The first cover portion 330a-1 may be made of a transparent dielectric material. In an exemplary embodiment, the first cover portion 330a-1 may be made of quartz glass or plastic. Further, the first cover portion 330a-1 may be made of the same material which forms the outer surface of the light source 320. Further, the first cover portion 330a-1 may be made of a flexible material. Further, a pressure-sensitive adhesive may be applied onto one surface of the first cover portion 330a-1 that comes in contact with the light source 320, that is, the inner surface of the first cover portion 330a-1. Thus, the light source 320 and the light guide unit 330 can be freely attached to or detached from each other.

The first cover portion 330a-1 may be fully hidden by the second cover portion 330a-2 such that only the second cover portion 330a-2 may be visible from outside the light radiation device 300. In an exemplary embodiment, the second cover portion 330a-2 may include black series pigments. The second cover portion 330a-2 may include carbon black or the same material as a black matrix 130, to be described later. The second cover portion 330a-2 may include a reflective material. Here, the reflective material may be applied onto one surface of the second cover portion 330a-2 that comes in contact with the first cover portion 330a-1, that is, the inner surface of the second cover portion 330a-2. The reflective material may reflect the light generated by the light source 320. Further, the second cover portion 330a-2 may be made of the same material as the above-described base substrate 310. Further, the second cover portion 330a-2 may be made of a flexible material.

The refractive index of the first cover portion 330a-1 may be higher than the refractive index of the second cover portion 330a-2. Further, the opacity of the first cover portion 330a-1 may be higher than the opacity of the second cover portion 330a-2. Further, the reflectivity of the first cover portion 330a-1 may be higher than the reflectivity of the second cover portion 330a-2.

The guide portion 330b may project from the cover portion 330a. In an exemplary embodiment, the guide portion 330b may project in a direction that is perpendicular to one surface of the cover portion 330a. The guide portion 330b may have a cylindrical shape, but is not limited thereto. The guide portion 330b may have various shapes depending on its application fields.

The guide portion 330b may be made of flexible optical fiber. For example, the guide portion 330b may include a rubber series material. In an exemplary embodiment, if an external force is not applied to the optical fiber, the optical fiber may be in a straight cylindrical shape. In another exemplary embodiment, if an external force is applied to the optical fiber, the optical fiber may be in a deformed cylinder shape, that is, the cylindrical shape that is bent in the direction of the external force.

At least two guide portions 330b may be provided. The guide portions 330b may be continuously arranged in one direction. In an exemplary embodiment, the one direction may be a direction that is parallel to the one surface of the base substrate 310. Further, the lengths of the guide portions 330b may be the same, but are not limited thereto. The lengths of some of the guide portions 330b may be different from the lengths of other guide portions 330b. In an exemplary embodiment, the surface that is formed through connection of end parts of the guide portions 330b may correspond to one surface of the cover portion 330a or the light source 320. In the exemplary embodiment illustrated in FIGS. 1 and 2, the surface that is formed to connect the end parts of the guide portions 330b has a curved shape, but is not limited thereto. The surface may be in a planar shape.

The guide portion 330b may include a first guide portion 330b-1 and a second guide portion 330b-2.

The first guide portion 330b-1 may be located in the center of the guide portion 330b. The first guide portion 330b-1 may come in direct contact with the first cover portion 330a-1. In an exemplary embodiment, the first guide portion 330b-1 may be fabricated integrally with the first cover portion 330a-1. The first guide portion 330b-1 may be made of a transparent dielectric material. In an exemplary embodiment, the first guide portion 330b-1 may be mode of quartz glass or plastic. Further, the first guide portion 330b-1 may be made of the same material as the first cover portion 330a-1.

The second guide portion 330b-2 may surround the first guide portion 330b-1. That is, the first guide portion 330b-1 may be fully hidden by the second guide portion 330b-2, and only the second guide portion 330b-2 may be visible when the light radiation device 300 is viewed from the outside. In an exemplary embodiment, the second guide portion 330b-2 may include black series pigments. Further, the second guide portion 330b-2 may include carbon black. Further, the second guide portion 330b-2 may be made of the same material as the black matrix 130 to be described later. Further, the second guide portion 330b-2 may include a reflective material. Here, the reflective material may be applied onto one surface of the second guide portion 330b-2 that comes in contact with the first guide portion 330b-1, that is, the inner surface of the second guide portion 330b-2. The reflective material may reflect the light which is generated from the light source 320 and is incident to the first guide portion 330b-1. Further, the second guide portion 330b-2 may be made of the same material as the above-described base substrate 310.

The refractive index of the first guide portion 330b-1 may be higher than that of the second guide portion 330b-2. Further, the opacity of the first guide portion 330b-1 may be higher than that of the second guide portion 330b-2. Further, the reflectivity of the first guide portion 330b-1 may be higher than that of the second guide portion 330b-2.

The emission portion 330c may be located on an end part of the guide portion 330b. The emission portion 330c may emit the light that has passed through the guide portion 330b to an outside of the light guide unit 330. The emission portion 330c may directly contact the first guide portion 330b-1. In an exemplary embodiment, the emission portion 330c may be fabricated integrally with the first guide portion 330b-1. The emission portion 330c may be made of a transparent dielectric material. In an exemplary embodiment, the emission portion 330c may be made of quartz glass or plastic. Further, the emission portion 330c may be made of the same material as the first guide portion 330b-1. Further, the emission portion 330c may be made of a material or a structure that can collect light, but is not limited thereto. The emission portion 330c may be made of a material or a structure that can diffuse the light, depending on its application field.

A part of the light generated from the light source 320 may be directly incident to the inside of the first guide portion 330b-1. On the other hand, another part of the light generated from the light source 320 may be reflected from one surface of the base substrate 310 that comes in contact with the light source 320, or from an interface between the first cover portion 330a-1 and the second cover portion 330a-2. A part of the reflected light may be incident to the inside of the first guide portion 330b-1. On the other hand, another part of the reflected light may be reflected again from the one surface of the base substrate 310 that comes in contact with the light source 320, or from the interface between the first cover portion 330a-1 and the second cover portion 330a-2. Through repetition of the above-described processes, most of the light that is generated from the light source 320 may be incident to the first guide portion 330b-1.

The light that is incident to the first guide portion 330b-1 may be totally reflected from the interface between the first guide portion 330b-1 and the second guide portion 330b-2. The light that is totally reflected from the interface between the first guide portion 330b-1 and the second guide portion 330b-2 may be transferred to the end part of the guide portion 330b with almost no light loss.

The light that is transferred to the end part of the guide portion 330b may be emitted to the outside of the light guide unit 330, that is, the outside of the light radiation device 300, through the emission portion 330c.

As described above, according to the light radiation device 300 according to an exemplary embodiment of the present invention, the light generated from the light source can be condensed by the light guide unit 330. If the condensed light is radiated onto a desired target, the loss of the light generated from the light source 320 can be minimized. Further, since the guide portion 330b is made of flexible optical fiber, the light can be radiated onto the desired target without causing damage, such as stretching of the target, to occur on the desired target even if the guide portion 330b is made to come in direct contact with the desired target. Further, since the guide portion 330b can be deformed, the light radiation can be easily performed even in a narrow region. Further, since the light emission region can be shifted from a region where the light source 320 is located to a region where the emission portion 330c is located, the light radiation interval can be easily adjusted.

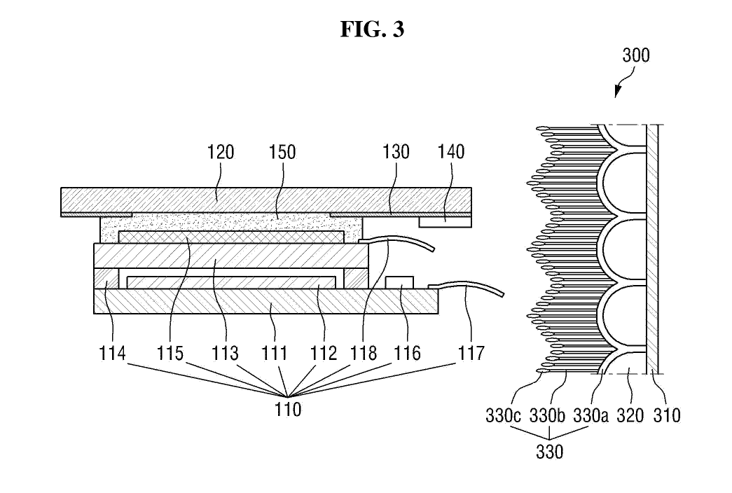

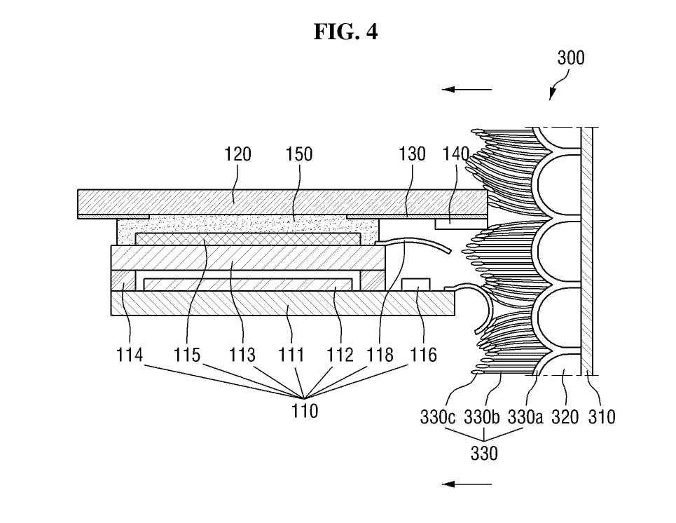

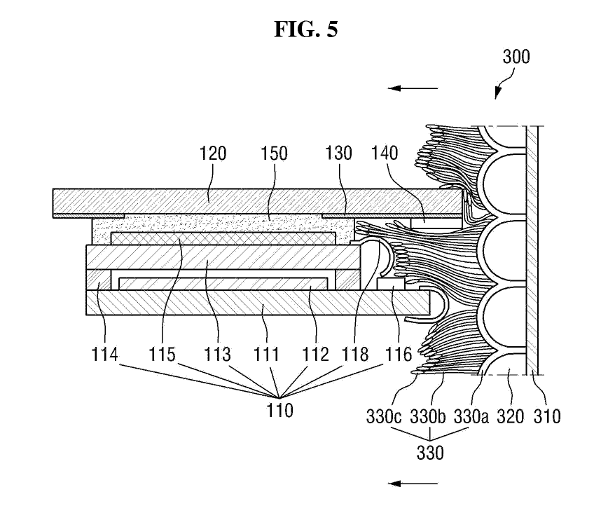

Hereinafter, a method for fabricating a display device according to an exemplary embodiment of the present invention will be described with reference to FIGS. 3 to 5. FIG. 3 is a cross-sectional view illustrating an arrangement of a display panel and a window, which are bonded to each other using photo-curable adhesives 150, so that side surfaces of the display panel 110 and the window 120 face the light radiation device 300 in a method for fabricating a display device according to an exemplary embodiment of the present invention. FIG. 4 is a cross-sectional view illustrating movement of a light radiation device 300 in a direction where a display panel 110 and a window 120, which are bonded to each other using photo-curable adhesives 1150, are located in a method for fabricating a display device according to an exemplary embodiment of the present invention. FIG. 5 is a cross-sectional view illustrating filling of a space between a display panel 110 and a window 120, which are bonded to each other using photo-curable adhesives 150, with a guide portion 330b of a light radiation device 300 in a method for fabricating a display device according to an exemplary embodiment of the present invention. For convenience in explanation, the same reference numerals are used for elements that are substantially the same as the elements illustrated in FIGS. 1 and 2, and the duplicate explanation thereof will be omitted.

In the exemplary embodiment described below, the display device may be any one of a liquid crystal display, an electrophoretic display, an organic light emitting display, an FED Field Emission Display), a SED (Surface-conduction Electron-emitter Display), a plasma display, and a cathode ray tube display. In the description below, the organic light emitting display is exemplified, but the present invention is not limited thereto.

The photo-curable adhesive 150 is cured by light. In an exemplary embodiment, the photo-curable adhesive may be a UV-curable resin, but is not limited thereto. Various kinds of photo-curable adhesives 150 may be used. If light is radiated onto the photo-curable adhesive 150, an organic material included in the photo-curable adhesive 150 is cross-linked and, thus, the photo-curable adhesive 150 is cured. Curing of the photo-curable adhesive 150 results in firm attachment of the target object and the photo-curable adhesive 150 which comes into contact with the target object.

The display panel 110 is a panel that displays an image. The display panel 110 includes a first substrate 111, a display portion 112, a second substrate 113, a sealant 114, a polarizing film 115, a driving portion 116, a first printed circuit board 117, and a second printed circuit board 118.

The first substrate 111 may be a thin film transistor substrate including a thin film transistor. The first substrate 111 may be made of transparent glass. Further, the first substrate 111 may be a flexible substrate.

The display portion 112 may be arranged on the first substrate 111. The display portion 112 may be a portion on which an image is displayed. The display portion 112 may include a plurality of pixels including an organic light emitting layer. Specifically, the pixels of the display portion 112 may include a first electrode, a second electrode, and an organic light emitting layer between the first electrode and the second electrode. If current is applied to the organic light emitting layer through the first electrode and the second electrode, light having specific color may be emitted from the organic light emitting layer. An image generated from the display portion 112 is shown through the polarizing film 115 and the window 120.

The second substrate 113 may be arranged to face the first substrate 111. The second substrate 113 may be an encapsulation substrate that protects the display portion 112 on the first substrate 111 from an external environment.

The sealant 114 may attach the first substrate 111 and the second substrate 113 to each other. The sealant 114 may be formed on an edge part of the display portion 112. The sealant 114 may be made of glass frit.

The polarizing film 115 may be formed on the second substrate 113. Specifically, the polarizing film 115 may be formed on one surface of the second substrate 113 that faces the window 120. The polarizing film 115 may suppress reflection of external light. FIGS. 3 to 5 illustrate the polarizing film 115, but the polarizing film 115 may be omitted.

The driving portion 116 may be located on the first substrate 111. In an exemplary embodiment, the driving portion 116 may be located on one end portion of the first substrate 111. The first substrate 111 may further project in one direction as compared with the second substrate 113, and the driving portion 116 may be arranged on the first projecting substrate 111. The driving portion 116 may transfer various signals for driving the display panel 110 to the display portion 112.

The first printed circuit board 117 may be located on the first substrate 111. In an exemplary embodiment, the first print circuit board 117 may be located on one end portion of the first substrate 111. For example, the first printed circuit board 117 may be arranged adjacent to the driving portion 116. The first printed circuit board 117 may be a main printed circuit board. That is, the first printed circuit board 117 may drive the display panel 110 through application of the various signals to the driving portion 116. The first printed circuit board may be flexible.

The second printed circuit board 118 may be located on the second substrate 113. In an exemplary embodiment, the second printed circuit board 118 may be located on one end portion of the second substrate 113. For example, the second printed circuit board 118 may be arranged adjacent to the driving portion 116 and the first printed circuit board 117. Further, at least a part of the second printed circuit board 118 may overlap the driving portion 116 or the first printed circuit board 117. The second printed circuit board 118 may be an auxiliary printed circuit board. That is, the second printed circuit board 118 may transfer an auxiliary signal, for example, a touch signal, to the display portion 112. Further, like the first printed circuit board 117, the second printed circuit board 118 may be flexible. The second printed circuit board 118 may, however, be omitted.

The window 120 may be arranged to face the display panel 110. Specifically, one surface of the window 120 may be arranged to face one surface of the second substrate 113 of the display panel 110. The window 120 may be made of reinforced glass. Further, the window 120 may be made of any suitable transparent material. Further, the window 120 may have a plate shape and may be large enough to fully cover the display panel 110.

The black matrix 130 may be formed on the edge part of the window 120. The black matrix 130 may be made of carbon black. The black matrix 130 may prevent complicated circuits that are located in a region that overlaps the black matrix 130, such as the driving portion 116, from being visible.

A third printed circuit board 140 may be located on one end part of the window 120. The third printed circuit board 140 may overlap the black matrix 130. The third printed circuit board 140 may be arranged adjacent to the driving portion 116, the first printed circuit board 117, and/or the second printed circuit board 118. In the same manner as the second printed circuit board 118, the third printed circuit board 140 may be an auxiliary printed circuit board.

Referring to FIG. 3, the display panel 110 and the window 120 may be bonded using the photo-curable adhesive 150. Here, the photo-curable adhesive 150 may provide some degree of adhesion prior to be being cured by the light. That is, the display panel 110 and the window 120 may be bonded to each other with a weak adhesive force by the photo-curable adhesive 150 prior to being cured by the light.

After the display panel 110 and the window 120 are bonded using the photo-curable adhesive 150, the guide portion 330b of the light radiation device 300 may be located to face side surfaces of the display panel 110 and the window 120. In an exemplary embodiment, some of the driving portion 116, the first printed circuit board 117, the second printed circuit board 118, and the third printed circuit board 140 may be disposed in close proximity to each other on one end part of the display panel 110. In this case, the guide portion 330b of the light radiation device 300 may be located to face the one end part of the display panel 110. In the exemplary embodiment illustrated in FIG. 3, the light radiation device 300 may be located only on one side part of the display panel 110, but is not limited thereto. The light radiation device 300 may be located on all the side parts, the upper part, and/or the lower part of the display panel 110. In this case, the guide portion 330b of the light radiation device 300 may be directed to the display panel 110 and the window 120.

Next, referring to FIG. 4, the light radiation device 300 is made to move in the direction where the display panel 110 and the window 120 are located and to come in direct contact with at least one of the display panel 110, the window 120, and the photo-curable adhesive 150. As the light radiation device 300 gradually moves toward the display panel 110 and the window 120, the shape deformation of the guide portion 330b increases. Further, as the light radiation device 300 moves in the direction where the display panel 110 and the window 120 are located, the guide portion 330b of the light guide unit 330 may be inserted between the display panel 110 and the window 120.

As described above, the light guide unit 330 that comes in direct contact with at least one of the display panel 110, the window 120, and the photo-curable adhesive 150 may be flexible. Accordingly, even if the light guide unit 330 comes in direct contact with at least one of the display panel 110, the window 120, and the photo-curable adhesive 150 to cause shape deformation, the display panel 110, the window 120, and the photo-curable adhesive 150 may remain undamaged. In the exemplary embodiment illustrated in FIG. 4, the light radiation device 300 is moved toward the display panel 110 and the window 120, but the present invention is not limited thereto. A bonded body of the display panel 110 and the window 120 may be moved in the direction where the light radiation device 300 is located.

Next, referring to FIG. 5, by locating the light radiation device 300 closer to the display panel 110 and the window 120, the deformed guide portions 330b can partially fill the region between the display panel 110 and the window 120. In an exemplary embodiment, the guide potion 330b can be disposed in a region where some of the driving portion 116, the first printed circuit board 117, the second printed circuit board 118, and the third printed circuit board 140 are closely positioned.

In this state, if power is applied to the light radiation device 300, light may be emitted from the emission portion 330c that is located at the end part of the guide portion 330b. That is, the light generated from the light source 320 may be guided by the light guide unit 330 and may be emitted from the region between the display panel 110 and the window 120. The light emitted from the region between the display panel 110 and the window 120 may cure the photo-curable adhesive 150 and, thus, the display panel 110 and the window 120 may be firmly bonded to each other.

In order to cure the photo-curable adhesive 150, light is radiated from an upper side of the window 120. In this case, since the black matrix 130 intercepts the light, the photo-curable adhesive 150 located below the black matrix 130 may not be sufficiently cured.

Accordingly, the light may be radiated not only from the upper side but also from the side part of the window 120. In this case, however, the driving portion 116 installed on the side of the display panel 110 or the window 120, the first printed circuit board 117, the second printed circuit board, and/or the third printed circuit board 140 may hide the side surface of the photo-curable adhesive 150. Because of this, the light that is radiated from the side part to cure the region below the black matrix 130 may be further intercepted by the driving portion 116, the first printed circuit board 117, the second printed circuit board, and/or the third printed circuit board 140 and, thus, curing may not be satisfactorily performed.

The uncured photo-curable adhesive 150 may cause a weak bonding between the display panel 110 and the window 120, and the photo-curable adhesive 150 may flow out to contaminate other neighboring structures. Installation of additional light sources 320 to increase the light quantity may cause problems, such as cost increases resulting from the installation of the additional light sources 320, narrow space for installing the additional light sources 320, and continuous maintenance management of the additionally installed light sources 320. Further, an overheating prevention control device for preventing overheating of the additional light sources 320 should be additionally provided, which could significantly increase costs.

According to the method for fabricating a display device according to an exemplary embodiment of the present invention, the light is emitted in a state where the light guide unit 330 is installed in the light radiation device 300, and the guide portion 330b of the light guide unit 330 is made to come in direct contact with at least one of the display panel 110, the window 120, and the photo-curable adhesive 150, thereby sufficiently curing the photo-curable adhesive 150. That is, by using the method for irradiating the light directly onto the photo-curable adhesive 150 rather than the method for indirectly irradiating the light onto the photo-curable adhesive 150, the photo-curable adhesive 150 can be prevented from flowing out, and poor bonding between the display panel 110 and the window 120 can be prevented. Further, since it is not necessary to install the additional light sources 320 and other additional devices, the existing equipment can be used as it is, and cost saving can be achieved and space utilization can be improved.

Because the guide portion 330b is made of a flexible optical fiber, damage, such as stretching, may not occur on the display panel 110 even if the guide portion 330b comes in contact with the display panel 110. Further, the guide portion 330b can be easily inserted into the narrow region between the display panel 110 and the window 120. For example, in the region where the first printed circuit board 117 is installed, and if the light is emitted from the end part of the guide portion 330b, that is, the emission portion 330c, in a state where the guide portion 330b is inserted into the narrow region to at least partially fill it up, it becomes possible to easily cure the photo-curable adhesive 150, which cannot easily occur in the related art.

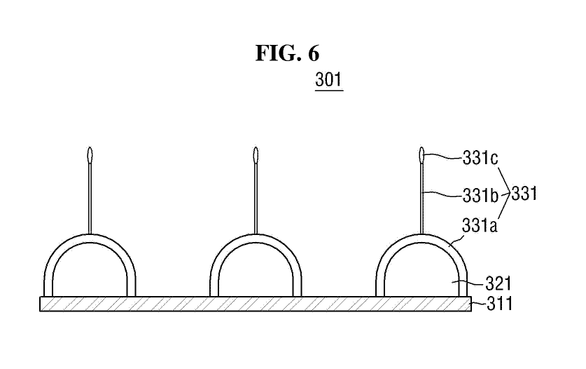

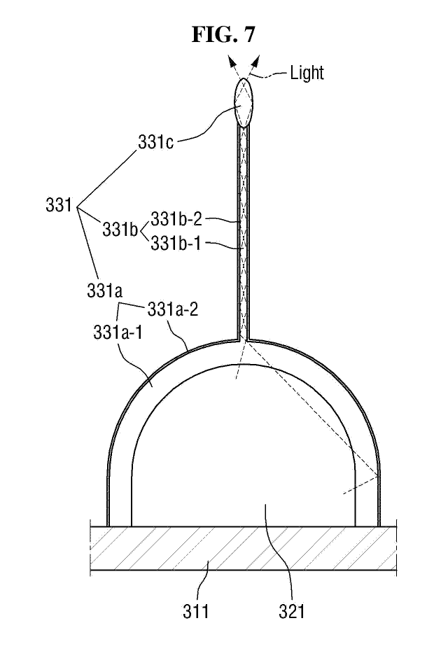

Hereinafter, a light radiation device 301 according to another exemplary embodiment of the present invention will be described with reference to FIGS. 6 and 7. FIG. 6 is a cross-sectional view of a light radiation device 301 according to another exemplary embodiment of the present invention, and FIG. 7 is an enlarged cross-sectional view of a part of the light radiation device 301 of FIG. 6. For convenience in explanation, the same reference numerals are used for elements that are substantially the same as those illustrated in FIGS. 1 and 2, and the duplicate explanation thereof will be omitted.

The light radiation device 301 includes a base substrate 311, a light source 321, and a light guide unit 331.

At least two light sources 321 may be provided, and the light sources 321 may be spaced apart from each other by a distance. Here, the distance may be adjusted corresponding to the radiation target.

The light guide unit 331 may include a cover portion 331a, a guide portion 331b, and an emission portion 331c. Here, the light guide unit 331, which is installed on each of the plurality of light sources 321, may include only one guide portion 331b. The one guide portion 331b may be arranged at a position corresponding to the center part of the light source 321.

The cover portion 331a may include a first cover portion 331a-1 and a second cover portion 331a-2. The guide portion 331b may include a first guide portion 331b-1 and the second guide portion 331b-2. The light generated from the light source 321 may be reflected from one surface of the base substrate 311, an interface between the first cover portion 331a-1 and the second cover portion 331a-2, or an interface between the first guide portion 331b-1 and the second guide portion 331b-2, and may be incident to the inside of the one guide portions 331b.

As described above, according to the light radiation device 301 according to another exemplary embodiment of the present invention, inhibition of light condensation can be further improved.

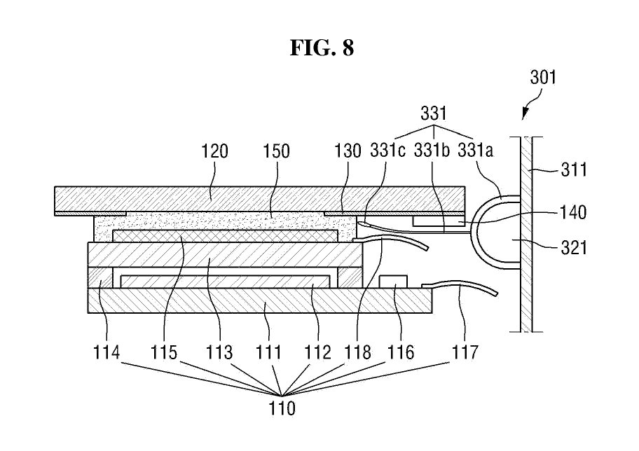

Hereinafter, a method for fabricating a display device according to another exemplary embodiment of the present invention will be described with reference to FIG. 8. FIG. 8 is a cross-sectional view illustrating insertion of a guide portion 331b of a light radiation device 301 between a display panel 110 and a window 120, which are bonded to each other using a photo-curable adhesive 150, in a method for fabricating a display device according to another exemplary embodiment of the present invention. For convenience in explanation, the same reference numerals are used for elements that are substantially the same as those illustrated in FIGS. 3 to 5, and the duplicate explanation thereof will be omitted.

According to the method for fabricating a display device according to another exemplary embodiment of the present invention, one guide portion 331b of the light radiation device 301 of FIG. 6 comes in direct contact with the photo-curable adhesive 150 interposed between the display panel 110 and the window 120, and the light is emitted through the emission portion 331c that is located at the end part of the guide portion 331b. Accordingly, the photo-curable adhesive 150 can be cured promptly and securely. Since the light condensation inhibition ability is improved, the curing of the photo-curable adhesive 150 can be performed more securely.

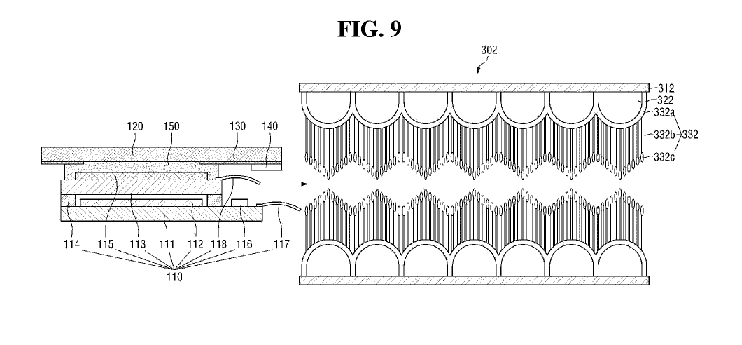

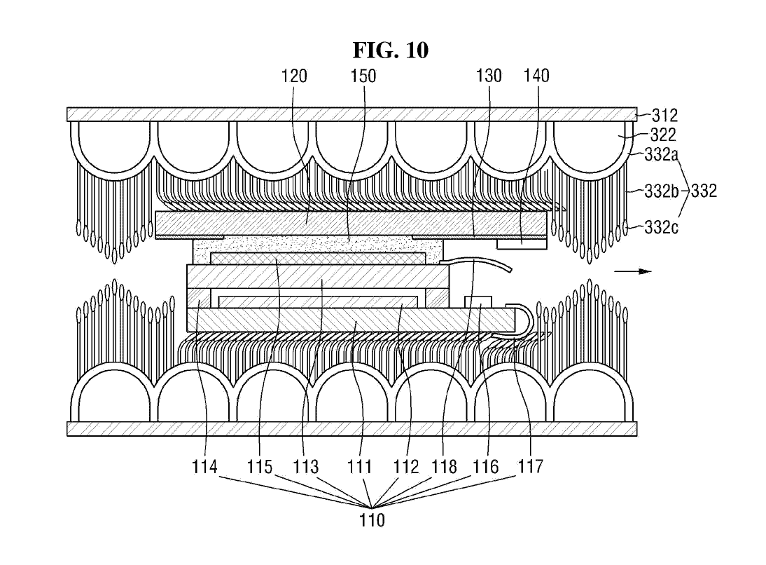

Hereinafter, a method for fabricating a display device according to still another exemplary embodiment of the present invention will be described with reference to FIGS. 9 and 10. FIG. 9 is a cross-sectional view illustrating an arrangement of a display panel 110 and a window 120, which are bonded to each other using a photo-curable adhesive 150, on one side of a plurality of light radiation devices 302, in to a method for fabricating a display device according to still another exemplary embodiment of the present invention. FIG. 10 is a cross-sectional view illustrating passing of a display panel 110 and a window 120, which are bonded to each other using a photo-curable adhesive 150, between at least two light radiation devices 302 in a method for fabricating a display device according to still another exemplary embodiment of the present invention. For convenience in explanation, the same reference numerals are used for elements that are substantially the same as those illustrated in FIGS. 3 to 5, and the duplicate explanation thereof will be omitted.

With reference to FIG. 9, the display device 110 and the window 120, which are bonded by the photo-curable adhesive 150, may be arranged on one side of the light radiation device 302. Here, at least two light radiation devices 302 may be provided. The light radiation device 302 may include a base substrate 312, a light source 322, and a light guide unit 332, and the light guide unit 332 of each of the light radiation devices 302 may face each other. That is, a cover portion 332a, a guide portion 332b, and an emission portion 332c of the light guide unit 332 may be directed to an inner region that is surrounded by the light radiation device 302. In an exemplary embodiment illustrated in FIG. 9, two light radiation devices 302 may be provided, and the guide portions 332b of the light radiation devices 302 may face each other.

Referring now to FIG. 10, the display device 110 and the window 120, which are bonded by the photo-curable adhesive 150, may be arranged on one side of the light radiation device 302, and a bonded body of the display panel 110 and the window 120 may be made to pass between the light radiation devices 302. As the bonded body of the display panel 110 and the window 120 passes between the light radiation devices 302, light guide units 332 of the light radiation devices 302 may directly contact the display panel 110 or the window 120. If the power is applied to the light radiation devices 302 in this state, light is emitted from the emission portions 332c located at the end parts of the guide portions of the light guide units 332 to cure the photo-curable adhesive 150.

As described above, according to the method for fabricating a display device according to still another exemplary embodiment of the present invention, the light emission portion is made to come in direct contact with the display panel 110 or the window 120 to shorten the light movement distance and, thus, the curing of the photo-curable adhesive 150 can be performed more securely.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. A method for fabricating a display device, comprising:
bonding a display panel to a window using a photo-curable adhesive; and
curing the photo-curable adhesive using a light radiation device,
wherein the light radiation device comprises:
a light source configured to generate light; and
a light guide configured to guide the light, the light guide unit comprising:
a cover covering the light source; and
a flexible optical fiber extending from the cover.

2. The method for fabricating a display device of claim 1, wherein the curing of the photo-curable adhesive comprises moving the light radiation device toward side surfaces of the display panel and the window, such that the optical fiber directly contacts at least one of the display panel, the window, and the photo-curable adhesive.

3. The method for fabricating a display device of claim 2, wherein the curing of the photo-curable adhesive comprises inserting the optical fiber between the display panel and the window.

4. The method for fabricating a display device of claim 3,
wherein the light radiation device comprises at least two of the optical fibers, and
wherein the curing of the photo-curable adhesive comprises inserting the optical fibers between the display panel and the window, such that at least one of the optical fibers is bent.

5. The method for fabricating a display device of claim 3,
wherein the display panel or the window comprises at least one printed circuit board, and
wherein the curing of the photo-curable adhesives comprises inserting the optical fiber into a region where the printed circuit board is installed.

6. The method for fabricating a display device of claim 1,
wherein the curing of the photo-curable adhesive comprises passing the display panel and the window between at least two of the light radiation devices.

7. The method for fabricating a display device of claim 6, wherein the curing of the photo-curable adhesive comprises directly contacting at least one of the display panel, the window, and the photo-curable adhesives with the optical fibers of the light radiation devices.

8. A method for fabricating a display device, comprising:
bonding a display panel and a window to each other using pa hoto-curable adhesive; and
curing the photo-curable adhesive by directly contacting at least one of the display panel, the window, and the photo-curable adhesive with a light radiation device.

9. The method for fabricating a display device of claim 8, wherein the light radiation device comprises:
a light source configured to generate light; and
a flexible optical fiber configured to guide the light,
wherein the curing of the photo-curable adhesives comprises directly contacting at least one of the display panel, the window, and the photo-curable adhesive with the optical fiber.

10. The method for fabricating a display device of claim 9, wherein the curing of the photo-curable adhesive comprises inserting the optical fiber between the display panel and the window, by moving of the light radiation device toward side surfaces of the display panel and the window.

11. The method for fabricating a display device of claim 10,
wherein the display panel or the window comprises a printed circuit board, and
wherein the curing of the photo-curable adhesive comprises inserting the optical fiber into a region where the printed circuit board is installed.

12. The method for fabricating a display device of claim 9,
wherein the curing of the photo-curable adhesive comprises passing the display panel and the window between at least two of the light radiation devices.
